(19) United States
(12) Patent Application Publication
(10) Pub. No.: US 2012/0268939 A1
(43) Pub. Date: Oct. 25, 2012

(54) METHOD OF LASER PROCESSING

(76) Inventors: Moshe Finarov, Rehovot (IL); Giora Dishon, Tel Aviv (IL); Ehud Tirosh, Mevaseret Zion (IL)

(21) Appl. No.: 13/533,424

(22) Filed: Jun. 26, 2012

Related U.S. Application Data
(63) Continuation of application No. PCT/IL2011/000041, filed on Jan. 13, 2011.

(30) Foreign Application Priority Data
Jan. 20, 2010 (IL) 203408

(51) Int. Cl. H01L 21/02; F21V 5/04

(52) U.S. Cl. 362/259; 438/795; 257/E21.002

(57) ABSTRACT

A method of manufacturing a waveguide within a substrate by local modification of material structure under high power density laser radiation applied from the mostly distant side of the substrate.

### CROSS-REFERENCE TO RELATED APPLICATIONS

This application is being filed under 37 U.S.C. 111 as a continuation application of International Application Number PCT/IL2011/000041 which has an international filing date of Jan. 13, 2011 and which claims priority to the patent application that was filed on Jan. 20, 2010 in Israel and assigned serial number 203408. The above-identified international application is presently pending at the filing of this application and includes at least one common inventor. This application claims the benefit of the priority date under 35 U.S.C. 120 of International Application Number PCT/IL2011/000041 which has an international filing date of Jan. 13 2011 and the Israeli patent application that was filed on Jan. 20, 2010 and assigned serial number 203408. This application incorporates the above-identified applications by reference in their entirety.

### TECHNOLOGY FIELD

The present apparatus and method relate to the field of bulk solid materials processing by ultra-fast laser exposure and more specifically to laser inscription within silicon wafers for example for creating in the wafer internal waveguides.

### BACKGROUND

The present invention relates to a field of processing bulk solid materials by help of ultra-fast laser exposure and more specifically for laser inscription inside silicon wafers, for example for creating internal waveguides.

Recent progress in generating ultra-fast pulse lasers has opened new material processing opportunities usually termed as micro-machining For example, it is now possible to modify material properties inside bulk materials using lasers with wavelength for which the processed materials are transparent. This is primarily due to multi-photon absorption and some other related phenomena which take place in transparent materials when light or radiation power density conveyed into the material exceeds a certain threshold. Such high power threshold is achievable by using high-power ultra-fast lasers by concentrating the emitted radiation energy into very short pulses in the range of femtoseconds to nanoseconds.

Most publications (see the attached list) and practical implementations relate to such transparent optical materials as glass, silica, Lithium Niobate, and some other materials. Processing of semiconductor materials such as for example, silicon having different types of crystalline structure has been much less investigated and implemented.

Recently it was shown that within silicon wafers that are usually used for manufacturing electronic devices it is possible to create an optical high frequency modulator. This enables creation of a new field of electro-optical devices and applications, which can be fully implemented within silicon chip. Development of this capability requires availability of a technique supporting formation of different optical paths and schemes for guiding optical beams within bulk silicon, which currently does not exists. One possible way of enabling controlled optical beam propagation within solid (bulk) material is to create a waveguide having desirable location, size and shape. Nejadmalayeri et al disclose an attempt to create optical waveguides in a bulk silicon wafer, relatively deep from the wafer surface. Nejadmalayeri used femtosecond laser pulses in IR spectral range with power sufficient to modify silicon structure and thus create channels of a predetermined shape with index of refraction different from the surrounding substrate. However, it was realized that “waveguides appeared at only very small distances of approximately 5-20 um below the silica-silicon interface, irrespective of the laser focusing depth (0-370 micrometer from the silica-silicon interface)”.

Accordingly, the problem of formation of different optical paths and schemes for guiding optical beams within bulk silicon as well as a method of modification of a transparent material by laser processing relatively deep from the surface of a silicon substrate remains not solved.

### GLOSSARY

In the context of the present disclosure the term “damage” represents any modification of an initial crystallographic structure such as crystallographic structure changes, structure amorphization, inducing in the substrate cracks, voids and the like. Such localized and shaped damaged region may serve as a waveguide, as an electrical isolation, as a center of impurity gettering, and may also be the basis for the creation of new solid state devices or improvement of existing ones.

### BRIEF SUMMARY

One aspect of the current method is based on forming a local continuously modified (e.g. damaged) region below the substrate front surface. The modified region or layer may be of an arbitrary 3D structure, a continuously modified layer and a partially modified layer, e.g. a matrix of modified material islands or volumes within the same layer

The present method includes exposure of a selected region of a substrate using ultra-short pulse focused laser beam with a wavelength at which the processed material is transparent. The laser beam is directed and focused into the substrate from the surface most distant relative to the desired location of the modified region. Such method of the laser beam focusing forms on the first illuminated surface of the substrate a relatively large spot with relatively low power density preventing formation of defects near the exposed surface.

It is another aspect of the current method to further minimize laser beam power density on the first exposed surface, by coating the surface by an anti-reflection coating (ARC) optimized for the used laser wavelength.

### BRIEF DESCRIPTION OF THE DRAWINGS

FIG. 1 is a schematic illustration of a waveguide example produced in depth of a silicon substrate;

FIGS. 2 and 3 are schematic illustration of a laser beam interaction with a silicon substrate by its illumination from a front and back substrate's sides, respectively;

FIG. 4 illustrates an interaction of a laser beam with the silicon substrate having an anti-reflection coating; and

FIGS. 5A and 5B (collectively referred to as FIG. 5) illustrate focusing of a laser beam within the silicon substrate using a reflective objective, which includes a mechanism for controlling aberrations.

### DESCRIPTION

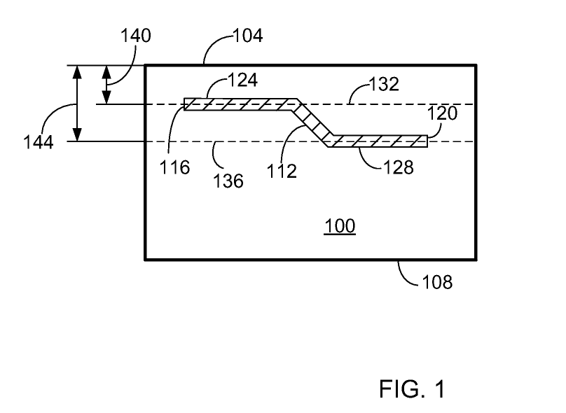

FIG. 1 is a schematic illustration of a waveguide example produced in depth of a silicon substrate. It schematically shows a single crystal silicon substrate 100 having a front surface 104 and a back surface 108. A waveguide 112 having a first end 116 and a second end 120 is produced in the substrate. Waveguide 112 is a three dimensional structure (3D) with refractive index different from the surrounding material. Waveguide 112 includes segments 124 and 128 shown as being parallel to substrate 100 surfaces, but their respective axes 132 and 136 may be located at different depths with respect to the surfaces of substrate 100. Axis 132 is located at a depth 140 and axis 136 is located at a depth 144. Although shown as located in the same plane (drawing plane), axes 132 and 136 may be located in different planes, oriented at an angle to each other, as it may be required by the desired waveguide (optical) path. It should be noted that any other materials may be used as the substrate and the materials may be of different crystalline structure e.g. polycrystalline, multi-crystalline, micromorphous and amorphous. Spatial (3D) location, dimensions and shape of the waveguide region and segments may be different (For example, a complete continuous layer spread over the whole substrate and coplanar to one of the surfaces or a partially modified layer, e.g. a matrix of modified material islands or volumes located within the same layer may be formed.) but in all of the variations the region of the waveguide is characterized by a different material structure relative to the surrounding region of substrate 100.

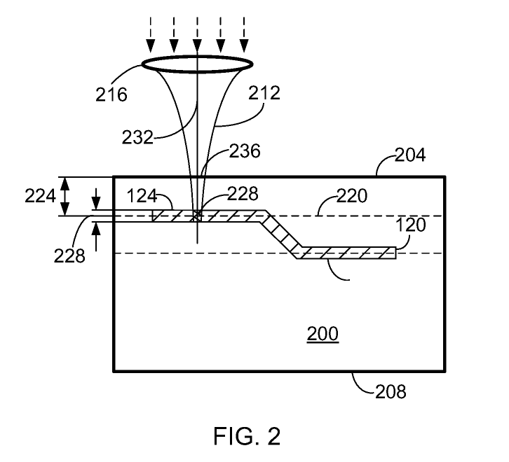

FIG. 2 schematically illustrates a known method of creating a different structure (a waveguide) in a pre-defined region within the substrate 200 having a front surface 204 and back surface 208. A beam of optical radiation 212, which may be a laser radiation beam, is focused by a lens 216 in plane 220, located at depth 224 below front surface 204 of substrate 200. In order to penetrate substrate 200 to a desired depth, spectral range, or at least a single wavelength of the used radiation, may be selected such that the substrate material would be substantially transparent at this wavelength or of the particular spectral range. In the vicinity of lens 216 focal plane 220, and in particular at the depth 224, the radiation density could be sufficiently high for causing modification of the substrate structure and form a volume 228 with a different material structure. It should be noted that focused laser radiation beam 212, propagating along an optical axis 232 causes increased radiation power density about the focal plane. If the focal plane is located below the first surface or front surface 204 of substrate 200, but relatively close to it, the power density at the front surface may be sufficiently high for causing surface damages within the surface area 236 and at a depth proximate or almost coinciding with the surface 204. This is because the surface layer of the substrate usually contains many structural defects, which could be centers absorbing the applied optical radiation and promoting further material damage generation. Therefore, a combination of high power density near the substrate surface and surface defects may create the damaged region at a shorter than the desired distance (shallower depth) from the substrate surface.

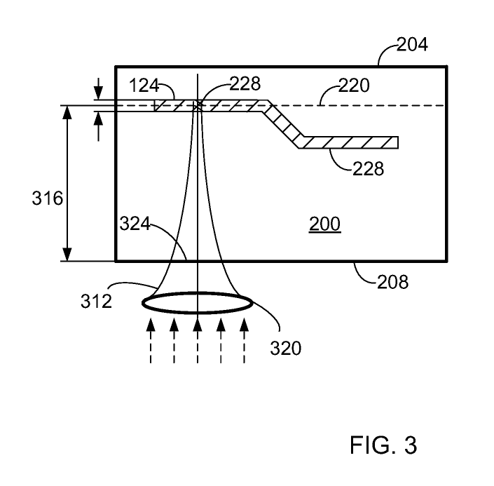

FIG. 3 schematically illustrates generation of a damaged region according to the present method. The damaged region could be formed within substrate 200 and may serve as a waveguide. In order to significantly reduce the probability of creating a damaged region proximate to the first surface 204, as it may happen in the above described method, the laser radiation 312 is applied from the back surface 208 of substrate 200, which is located most distantly from said trajectory first end. FIG. 3 illustrates that a distance 316 of pre-determined plane 220 from the “first” illuminated surface, which is now surface 208, is substantially larger than from the front surface 204. Lens 320 focuses radiation 312 at the focal plane 220 creating within depth 316 of substrate 200 a power density sufficient for modification of substrate 200 material structure. The modification of the substrate may be such that a trajectory defining a continuous region structure will be modified, a complete layer of material spread all over the substrate coplanar with one of the surfaces will be modified or a partially modified layer, e.g. a matrix of modified islands or volumes located within the layer. Since the distance from the first illuminated surface 208 to the focal plane 220 is relatively large, the illuminated by laser radiation spot 324 on surface 208 is also large and the power density within the spot is relatively low. Such low power density prevents formation of defects at surface 208 or in layers/volumes of substrate 200 proximate to the surface.

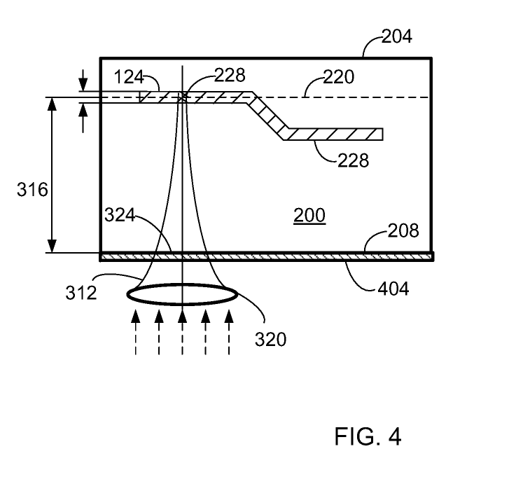

It should be noted that FIGS. 2 and 3 as well as FIG. 4 are schematic figures and the path of optical rays does not account for changes in direction of the rays, which according to the Snell law occur when optical radiation propagates from a medium with one refractive index into a medium with a different refractive index.

FIG. 4 schematically illustrates another example of a method of creating a damaged region according to the present method. In order to reduce the laser's power as well as probability of potential damage to the “first” surface 208 of substrate 200, surface 208 is coated by a thin transparent film 404 serving as an anti-reflection coating (ARC). In the case of silicon substrate the coating may be such as silicon nitride, which has an index of refraction close to a root square of the index of refraction of silicon. Such condition ensures adequate ARC performance. Typically, optical thickness, which is a multiple of geometrical thickness of the film and index of refraction of the film, would be a quarter of the selected wavelength of the laser radiation. Such ARC can be produced by several manufacturing methods like chemical vapor deposition (CVD), vacuum physical deposition (sputtering), and others.

The ARC enables to significantly reduce the power of the laser source; in a case of a silicon substrate the ARC reduces the surface reflectance from about 40% to about zero percent. Because of this, the required laser power may be reduced on a similar factor as compared to laser power required to induce a damage in the substrate without the ARC. The lower power of the laser source reduces the radiation power density at the first illuminated surface and therefore reduces probability of causing or developing undesired defects near this surface. In addition to this, use of a lower power laser reduces the cost of the apparatus for making waveguides in the substrate.

In the examples illustrated in FIG. 3 and FIG. 4 the substrate is a silicon wafer with thickness of 0.5 mm to 6.0 mm and the desired depth of the damaged region is in the range of 50 micrometer to 5 mm from the front surface. In particular tests the selected inscription plane was located about 200 um below the surface of the substrate which is first illuminated by the radiation or front surface.

The produced by the present method waveguide structure typically had a “tube-like cross section” with about 10 micrometer diameter centered around the axis of the tube, located in the plane parallel to the substrate surface. Laser wavelength selection criteria were generally accounting for silicon transparency characteristics, which are known to be transparent for wavelengths larger than 1.1 micrometer. Laser radiation power selection criteria were based on selection of power sufficient to create damages in silicon thereby modifying silicon structure and generation of power density sufficient for creating a multi-photon absorption, which is known to be in the range of 1 mJ/cm² to 10 J/cm².

The required laser power density was produced by focusing laser radiation in a very small volume, e.g. a volume of about several micrometers in diameter, during a short pulse, e.g. in the range from several femto-seconds to a few nano-seconds.

Typical set-up parameters were:

Erbium (Er) Fiber Laser Smart Light MD10, commercially available from Raydiance, Inc., Petaluma Calif. U.S.A., with the following specified characteristics:
Laser Wavelength: 1552 nm
Energy per pulse: 10 μJ
Pulse width (typical): 800 fs
Repetition Rate: 1 Hz-300 kHz
Average Power: 3 Watts
Beam Diameter: 4 mm
Beam Divergence: 1 milliradian

The emitted beam was focused into a spot of about 10 micrometer diameter providing in a single pulse a power density of about 10 J/cm2, which proved to be sufficient for generating two-photon absorption in the irradiated volume.

The parameters of other set-up elements shown in FIG. 3 and FIG. 4 relate mainly to the laser beam focusing lens 216 and 316. This objective lens was selected based on the following criteria, although other criteria may be employed in selecting a similar lens:

High numerical aperture (NA) ensuring minimal depth of focus around the focal plane;

Large working distance allowing moving the focal plane within the substrate in a relatively large range, e.g. up to several millimeters from the front surface in the depth of the substrate;

High resolution, ensuring minimum aberrations and providing maximal power density of the focused laser radiation within the processed substrate volume;

Aberration compensation mechanism, which minimizes aberrations as focusing depth changes;

High transmittance at the selected wavelength, i.e. 1552 nm minimizing losses of laser radiation power;

High damage threshold although supporting safe operation with high power, short pulse laser radiation.

An off-the-shelf reflective Schwarzschild objective #506-120 commercially available from Davin Optronics Ltd. (Watford-Hertz, UK) [www.davincatalogue.com] met most of the above criteria. Below are listed the parameters of the objective lens:
NA: 0.65
Focal length: 3.55 mm
Working distance: 1 9 mm
Small minor diam.: 4 6 mm
Reflectance: 98% (gold coating):
   The objective includes an adjustment mechanism operative to compensate for the optical aberrations induced by the additional optical thickness within the working distance.

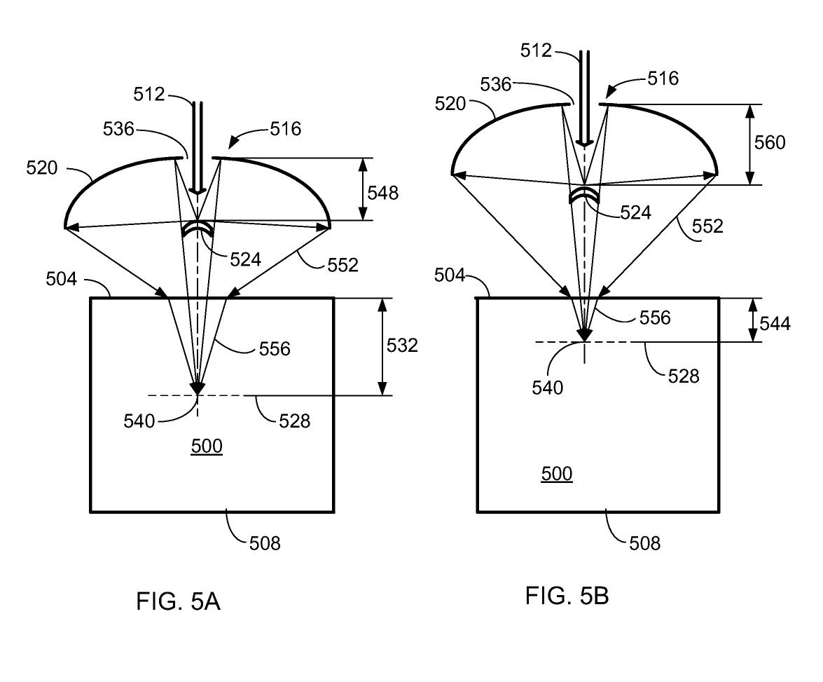

An apparatus for generating waveguides in a substrate according to the present method and employing the above components is schematically illustrated in FIGS. 5A and 5B, where two different distances (532 and 544) of the focal plane relative to the first substrate surface are shown.

A substrate 500, which may be a silicon wafer or any other suitable substrate has a first or front surface 504, which may be either the front or the back surface, and the second or back surface 508. Laser beam 512 is focused by a reflective objective 516, for example such as Schwarzschild objective #506-120. The objective includes a first minor 520 and a second minor 524. In FIG. 5A, Focal plane 528 of objective 516 is located at a distance 532 from the front illuminated surface 504. Laser beam 512 enters objective 516 through first mirror 520 aperture 536 and it impinges on second minor 524, which reflects the incident beam into a large angular range. All light beams reflected by second minor 524 are then reflected by first mirror 520 and focused into a small spot 540 in the focal plane 528.

The spot size is limited by diffraction, i.e. by the NA of the objective and laser wavelength, as well as by aberrations of the optical system. The major contributor to the optical aberration is the silicon layer through thickness 532 of which light beam 512 has to propagate until it reaches focal plane 528 where the waveguide is to be formed. In order to minimize this aberration, the distance 548 between the first and the second mirrors of objective 516 may be adjusted to an optimal value.

The waveguides may be created within the substrate in one plane or in multiple planes. The waveguides may be created to affect the desired segments/volumes of a plane/layer or even a complete layer spread all over the substrate. In some cases the desired waveguide pattern may be located at different depths within the substrate, which may be a silicon wafer or other substrate. FIG. 5B illustrates objective 516 refocused to affect substrate 500 at a depth 544 different from depth 532 (FIG. 5A). In order to keep the minimal spot size in the focal plane and compensate for aberrations that may be caused by the change in thickness of the substrate layer, the distance between first 520 and second 524 mirrors of the objective will be adjusted accordingly as shown by distance 560.

The refractive index of the substrate is higher than that of the air and according to the Snell law oblique incidence rays, such as rays 552, are refracted by the substrate and propagate at smaller, as measured to the perpendicular to the surface, angles, shown by the marginal ray 556. The higher index of refraction of the substrate, the stronger the refraction. The stronger the refraction, the higher the power density of the incident illumination at the substrate surface. In materials with relatively low index of refraction such as glass or silica this effect is small. However, in materials with high index of refraction like silicon this effect is very strong. Therefore generating near-surface defects with laser illumination is more likely to happen in silicon than in silica.

The described approach of processing substrates can be used for modification production of the desired/required trajectories defining a continuous region structure or separate volumes of waveguides by providing a relative displacement between the substrate and the focused spot. This may be achieved either by moving the substrate or by moving the optics or by a combined movement of both the substrate and the optics. The velocity of such movement depends on the power of the optical radiation provided by the laser, which in case of a pulsed laser depends on the repetition rate of the laser. A certain overlap between adjacent laser spots selected to provide a continuous modified by laser radiation material structure (line or plane) may be provided. The distance of the focal plane relative to the first illuminated surface may also be changed in course of desired waveguide trajectory formation. Such change of distance will be synchronized with simultaneous compensation for the induced aberrations caused by the change in the focal plane location.

One of the potential applications of the method described is production of photonics devices, for example formation of waveguides in silicon. Other possible applications are in areas such as microelectronics and photo-voltaic solar cells manufacturing, wafers marking and others.

Although the method and apparatus implementing the method have been described in conjunction with specific examples thereof, it is evident that many alternatives, modifications and variations will be apparent to those skilled in the art. Accordingly, the description is intended to embrace all such alternatives, modifications and variations that fall within the spirit and broad scope of the appended claims:

What is claimed is:

1. A method of processing a silicon substrate having a first and a second surface, the method comprising:
selecting within said substrate a continuous region, the structure of which has to be modified by said processing; and
selecting the surface of said substrate located most distantly from said continuous region;
modifying the substrate structure in said continuous region by illuminating with a focused laser beam from the selected surface of said substrate and moving the focused laser beam along said continuous region.

2. The method according to claim 1, wherein the silicon substrate has a structure being at least one of a group of structures consisting of single crystal, polycrystalline, multi-crystalline, micro-morphous, and amorphous structures.

3. The method according to claim 1, wherein the surface most distantly located from said continuous region is in the range of 50 micrometer to 5 mm.

4. The method according to claim 1, wherein said laser beam has a wavelength at which the material of said substrate is transparent and wherein said wavelength is longer than 1.1 micrometer.

5. The method according to claim 1, wherein said laser beam is a pulsed radiation laser beam with pulse duration in the range from several femto-seconds to a few nano-seconds and wherein the power density of each pulse of said laser beam in focus is in the range of 1 mJ/cm² to 10 J/cm2.

6. The method according to claim 1, wherein said substrate surface most distantly located from said continuous region is coated by an anti-reflection coating for a particular laser wavelength and wherein the anti-reflection coating is made of silicon nitride.

7. The method according to claim 1, wherein said modified structure is provided in a continuous modified substrate layer and wherein the continuous modified layer is spread all over the substrate.

8. The method according to claim 1, wherein said movement of said focused laser beam is done in at least one of three orthogonal directions and wherein at least one of the three orthogonal directions is along the focused laser beam propagation direction.

9. The method according to claim 8, wherein during said movement along the laser beam propagation direction aberrations in the optical path are compensated by change in distance between first and second mirrors of objective and wherein the distance between the mirrors is in accordance with the depth of the processed region.

10. The method according to claim 1, further comprising modifying the substrate structure by progressing from exposure by the focused laser beam of the regions located deeper from the surface through which the laser beam is introduced and continue to regions located closer to that surface.

11. An apparatus for generating a modified material structure in a substrate, comprising:
a laser emitting a laser beam;
an objective configured to focus the laser beam in the material the structure of which has to be modified; and
an aberration compensation mechanism supporting change of the distance between components of the objective to compensate for aberrations introduced by the substrate material.

12. The apparatus according to claim 11, wherein the laser is an Erbium fiber laser emitting a laser beam with a wavelength of 1552 nm.

13. The apparatus according to claim 11, wherein the objective is a Schwarzschild objective configured to focus the laser beam in the material through a surface of the material which is located most distantly from the structure which has to be modified into a diffraction limited spot with intensity sufficient to generate a two-photon absorption in the material and modify the refraction index of the material.
